(19) United States
(12) Patent Application Publication
(10) Pub. No.: US 2025/0015493 A1
(43) Pub. Date: Jan. 9, 2025

(54) OUTPUT POWER CONTROL FOR A BEAMFORMING TRANSMISSION SYSTEM

(71) Applicant: Agency for Science, Technology and Research, Singapore (SG)

(72) Inventors: Yong Joon JEON, Singapore (SG); Kumarasamy Raja MUTHUSAMY, Singapore (SG)

(21) Appl. No.: 18/710,032

(22) PCT Filed: Nov. 16, 2022
(86) PCT No.: PCT/SG2022/050829

§ 371 Date: May 14, 2024

(30) Foreign Application Priority Data
Nov. 16, 2021 (SG) 10202112750W

(51) Int. Cl. H01Q 3/28; H03F 3/24

(52) U.S. Cl. CPC H01Q 3/28; H03F 3/245; H03F 2200/451

(57) ABSTRACT

A beamforming transmission system and a method of controlling an output power of a beamforming transmission system are disclosed, the system comprising one or more transmission elements, the one or more transmission elements each comprising a power amplifier; an antenna coupled to the power amplifier; and a power detector coupled to the antenna; a power controller coupled to the power amplifier; a system processing module coupled to the one or more transmission elements, the system processing module further coupled to the power controller, the system processing module being arranged to instruct the power controller to control an output power of the power amplifier; wherein the system processing module is arranged to determine a desired beam scanning angle of the one or more transmission elements and to obtain a present output power of the power amplifier from the power detector; and further wherein the system processing module is arranged to instruct the power controller to control the output power of the power amplifier based on both the desired beam scanning angle and the present output power of the power amplifier.

### TECHNICAL FIELD

The present disclosure relates broadly to a beamforming transmission system and to a method of controlling an output power of a beamforming transmission system.

### BACKGROUND

Phased array systems typically comprise one or more beamforming (or beam forming) elements that in turn each include an antenna and a beamforming integrated chip (IC). In such systems, the beamforming elements transmit and receive electromagnetic signals so that these signals can be constructively combined in a coherent phase and in amplitude.

To implement beam scanning at a certain/predetermined angle, it has been recognized that RF (radio frequency) phase shift control and gain control are desired to be provided. FIG. 1 is a schematic drawing illustrating scanning losses with respect to beam scanning angles in a phased array system. It may be observed that a beam scanning angle at 30 degrees may encounter negligible scanning loss. Refer to numeral 102. It has been recognized that at more extreme angles, Effective Isotropic Radiated Power (EIRP) is reduced due to lesser antenna gain. For example, referring to FIG. 1, when the beam scanning angle is greater than 50 degrees, the scanning loss becomes larger than 5 dB due to lesser antenna gain. Refer to e.g. numeral 104. Conventionally, the data rate for communication is reduced to keep the link signal to noise ratio (SNR).

The inventors recognize that, to compensate for the increased scanning loss and to keep the SNR in the communication link for high spectral efficiency, the beamforming elements may be operated at high/maximum power to increase/maximise their output powers. However, the inventors also recognize that such high power is not needed if the scanning angle is lower, e.g. below 50 degrees. The beamforming elements are recognized to show poor power efficiency when high power is not needed, e.g. if lower power is sufficient.

Hence, in view of the above, there exists a need for a beamforming transmission system and a method of controlling an output power of a beamforming transmission system that seek to address at least one of the above problems.

### SUMMARY

In accordance with an aspect of the present disclosure, there is provided a beamforming transmission system, the system comprising one or more transmission elements, the one or more transmission elements each comprising a power amplifier; an antenna coupled to the power amplifier; and a power detector coupled to the antenna; a power controller coupled to the power amplifier; a system processing module coupled to the one or more transmission elements, the system processing module further coupled to the power controller, the system processing module being arranged to instruct the power controller to control an output power of the power amplifier; wherein the system processing module is arranged to determine a desired beam scanning angle of the one or more transmission elements and to obtain a present output power of the power amplifier from the power detector; and further wherein the system processing module is arranged to instruct the power controller to control the output power of the power amplifier based on both the desired beam scanning angle and the present output power of the power amplifier.

The beamforming transmission system may further comprise the system processing module being arranged to instruct the power controller to control the output power of the power amplifier based on one of at least a first operating point of the power amplifier and a second operating point of the power amplifier.

The beamforming transmission system may further comprise the system processing module being arranged to instruct the power controller to control the output power of the power amplifier using the first operating point of the power amplifier at a first power mode and using the second operating point of the power amplifier at a second power mode, the first power mode and the second power mode being based on both the desired beam scanning angle and the present output power of the power amplifier.

The first operating point may comprise a first predetermined set of values of a supply voltage and a supply current to the power amplifier and the second operating point may comprise a second predetermined set of values of the supply voltage and the supply current to the power amplifier.

The power controller may comprise a supply voltage generator coupled to the power amplifier and a separate bias current generator coupled to the power amplifier, both the supply voltage generator and the bias current generator being coupled to the system processing module; and wherein the system processing module is arranged to simultaneously adjust the supply voltage generator and the separate bias current generator based on the one of at least a first operating point of the power amplifier and a second operating point of the power amplifier to provide the respective supply voltage and the supply current to the power amplifier.

The respective supply voltage and the supply current to the power amplifier may be adjustable independently of each other.

The power controller may comprise a power mode controller coupled to the power amplifier and a bias current generator coupled to the power amplifier, both the power mode controller and the bias current generator being coupled to the system processing module; and wherein the system processing module is arranged to switch on or off the power amplifier, the switch on or off being independent of at least one other power amplifier of the one or more transmission elements.

The system processing module may be arranged to switch on or off the power amplifier based on the one of at least a first operating point of the power amplifier and a second operating point of the power amplifier.

The beamforming transmission system may further comprise a memory component to store one or more settings for the system processing module to instruct the power controller to control the output power of the power amplifier based on both the desired beam scanning angle and the present output power of the power amplifier.

In accordance with another aspect of the present disclosure, there is provided a method of controlling an output power of a beamforming transmission system that comprises one or more transmission elements, the one or more transmission elements each comprising a power amplifier; an antenna coupled to the power amplifier; and a power detector coupled to the antenna, the method comprising determining a desired beam scanning angle of the one or more transmission elements; obtaining a present output power of the power amplifier from the power detector; controlling, using a power controller of the beamforming transmission system, the output power of the power amplifier based on both the desired beam scanning angle and the present output power of the power amplifier.

The method may further comprise controlling the output power of the power amplifier based on one of at least a first operating point of the power amplifier and a second operating point of the power amplifier.

The method may further comprise controlling the output power of the power amplifier using the first operating point of the power amplifier at a first power mode and using the second operating point of the power amplifier at a second power mode, the first power mode and the second power mode being based on both the desired beam scanning angle and the present output power of the power amplifier.

The first operating point may comprise a first predetermined set of values of a supply voltage and a supply current to the power amplifier and the second operating point may comprise a second predetermined set of values of the supply voltage and the supply current to the power amplifier.

The method may further comprise providing a supply voltage generator coupled to the power amplifier and a separate bias current generator coupled to the power amplifier; and simultaneously adjusting the supply voltage generator and the separate bias current generator based on the one of at least a first operating point of the power amplifier and a second operating point of the power amplifier to provide the respective supply voltage and the supply current to the power amplifier.

The method may further comprise adjusting the respective supply voltage and the supply current to the power amplifier independently of each other.

The method may further comprise providing a power mode controller coupled to the power amplifier and a bias current generator coupled to the power amplifier; and switching on or off the power amplifier, the switching on or off being independent of at least one other power amplifier of the one or more transmission elements.

The method may further comprise switching on or off the power amplifier based on the one of at least a first operating point of the power amplifier and a second operating point of the power amplifier.

The method may further comprise storing one or more settings in a memory component of the beamforming transmission system, the one or more settings for instructing the power controller to control the output power of the power amplifier based on both the desired beam scanning angle and the present output power of the power amplifier.

In accordance with another aspect of the present disclosure, there is provided a computer readable storage medium having stored thereon software instructions that, when executed by a system processing module of a beamforming transmission system, cause the system processing module to perform a method of controlling an output power of a beamforming transmission system disclosed herein.

### BRIEF DESCRIPTION OF THE DRAWINGS

Exemplary embodiments of the present disclosure will be better understood and readily apparent to one of ordinary skill in the art from the following written description, by way of example only, and in conjunction with the drawings, in which:

FIG. 1 is a schematic drawing illustrating scanning losses with respect to beam scanning angles in a phased array system.

FIG. 2 is a schematic block diagram for illustrating a beamforming transmission system in an exemplary embodiment.

FIG. 3 is a schematic diagram of a beamforming transmission system in another exemplary embodiment.

FIG. 4 is a schematic drawing to illustrate load lines for a power amplifier in a beam forming array.

FIG. 5 is a graph showing simulated results of power-added efficiency (PAE) and output power (Pout) of a power amplifier to show a drop in efficiency if an operating point of the power amplifier is not adjusted.

FIG. 6A is a graph showing simulated results of power-added efficiency (PAE) and output power (Pout) of the power amplifier of FIG. 5 with a first different operating point in an exemplary embodiment.

FIG. 6B is a graph showing simulated results of power-added efficiency (PAE) and output power (Pout) of the power amplifier of FIG. 5 with a second different operating point in an exemplary embodiment.

FIG. 7 is a graph for illustrating a change in power-added efficiency (PAE) of a power amplifier with respect to a change in a supply bias current to the power amplifier at a fixed output power in an exemplary embodiment.

FIG. 8 is a schematic diagram of a beamforming transmission system in another exemplary embodiment.

FIG. 9 is a schematic diagram for illustrating the power controller of FIG. 8 in an exemplary embodiment.

FIG. 10 is a schematic diagram for illustrating the power controller of FIG. 8 in another exemplary embodiment.

FIG. 11 is a schematic flowchart for illustrating a method of controlling an output power of a beamforming transmission system in an exemplary embodiment.

FIG. 12 is a schematic flowchart for illustrating an exemplary decision process for controlling an output power of a beamforming transmission system.

FIG. 13 shows an example of a supply voltage generator.

FIG. 14 shows an example of a bias current generator.

### DETAILED DESCRIPTION

Exemplary embodiments described herein can provide a beamforming transmission system that may provide an adaptive close loop control of the output power of the beamforming transmission system and a method of controlling an output power of a beamforming transmission system. The method may allow adjusting/adjustment of an output power or gain of an array or one or more transmission elements whereby the method comprises adjusting/controlling at least one power amplifier for the array or the one or more transmission elements to control the output power of the at least one power amplifier and whereby the adjusting/controlling is based on a desired/decided/determined beam scanning angle and a detected present/current output power level of the at least one power amplifier.

In exemplary embodiments, the output power of one or more transmission elements can be controlled via an adaptive closed loop control. For example, based on a desired beamforming or beam steering or beam scanning angle of the beamforming transmission system of the one or more transmission elements and based on a detected present/current output power of the beamforming transmission system, one or more settings may be determined/retrieved to control the output power of the beamforming transmission system. As one transmission element comprise a power amplifier and a power detector, the description herein is based on such components of the one transmission element and can be extended to the beamforming transmission system (that comprises the one or more transmission elements). For example, control of the output power of the power amplifier, power detection from the power detector etc. may be extended to the one or more transmission elements. In one exemplary embodiment, the one or more settings may comprise instructions for controlling a supply voltage and a supply bias current simultaneously. In another exemplary embodiment, the one or more settings may comprise instructions for on/off control of at least one power amplifier of the one or more transmission elements.

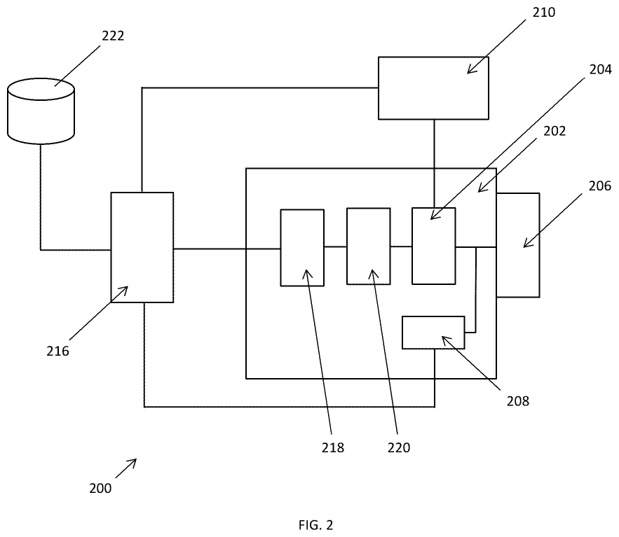

FIG. 2 is a schematic block diagram for illustrating a beamforming transmission system in an exemplary embodiment. The beamforming transmission system 200 comprises one or more transmission elements e.g. 202. Each of the one or more transmission elements e.g. 202 comprises a power amplifier 204, an antenna 206 coupled to the power amplifier 204 and a power detector 208 coupled to the antenna 206. The transmission system 200 also comprises a power controller 210 coupled to the power amplifier 204 and a system processing module 216 coupled to the power controller 210. The system processing module 216 is also coupled to the one or more transmission elements e.g. 202. In the exemplary embodiment, the system processing module 216 is capable of, and is arranged to, instructing/instruct the power controller 210 to control an output power of the power amplifier 204.

In the exemplary embodiment, to control the output power of the power amplifier 204, the system processing module 216 is arranged to determine a desired beam scanning angle of the one or more transmission elements e.g. 202 and to also obtain a present/current output power of the power amplifier 204 from the power detector 208. Based on both the desired beam scanning angle and the present output power of the power amplifier 204, the system processing module 216 is capable of instructing, or is arranged to instruct, the power controller 210 to control the output power of the power amplifier 204.

In the exemplary embodiment, the transmission system 200 comprises additional components. Each of the one or more transmission elements e.g. 202 comprises a transmission element controller 218. For example, the transmission element controller 218 may be in the form of a transmission element integrated chip (IC) or beamforming/beamformer IC. Each of the one or more transmission elements e.g. 202 also comprises a phase shifter and gain adjustment member 220 coupled to the transmission element controller 218. The phase shifter and gain adjustment member 220 is communicatively coupled to the power amplifier 204 and is controllable for its phase shifter value. The gain of the power amplifier 204 is adjustable/controllable based on the desired beam scanning angle.

In the exemplary embodiment, the transmission system 200 further comprises a memory component 222 to store one or more settings for the system processing module 216 to instruct the power controller 210 to control the output power of the power amplifier 204 based on both the desired beam scanning angle and the present output power of the power amplifier. For example, the memory component 222 may be in the form of a storage device/module that comprises a Random Access Memory (RAM) chip/component. The memory component 222 may contain a database that is in a form of, for example only, one or more look-up tables (LUTs). In the exemplary embodiment, the one or more settings may be stored in the memory component 222 in advance of an operation of the one or more transmission elements e.g. 202.

As an example, a LUT may be created in advance that contains a list of beam scanning angles with each linked to a corresponding setting for a power amplifier, a phase shifter and a gain adjustment member. For example, for a beam scanning angle of 30 degrees, a corresponding setting (e.g. for a low power mode) is linked and stored in the LUT. For example, for a beam scanning angle of 50 degrees, a corresponding setting (e.g. for a high power mode) is linked and stored in the LUT. For example, for a beam scanning angle of an extreme angle (e.g. more than 50 degrees), a corresponding setting (e.g. for a maximum power mode) is linked and stored in the LUT. As such, it is possible for an output power and/or gain and/or phase of a transmission element integrated chip (IC) or beamforming/beamformer IC (that comprises a power amplifier) to be adjusted using a setting based on a desired beam scanning angle and a detected present output power of the power amplifier.

In the exemplary embodiment, the one or more settings may comprise a plurality of different operating points of the power amplifier 204, i.e. at least a first operating point of the power amplifier 204 and a second operating point of the power amplifier 204. The system processing module 216 is capable of instructing the power controller 210 to control the output power of the power amplifier 204 based on one of the plurality of different operating points. In the exemplary embodiment, the system processing module 216 is capable of instructing the power controller 210 to control the output power of the power amplifier using one operating point of the power amplifier at a first power mode (e.g. a low power mode) and using another different operating point of the power amplifier at a second power mode (e.g. a high power mode). The system processing module 216 determines the first power mode and the second power mode based on both the desired beam scanning angle and the present output power of the power amplifier.

In some exemplary embodiments, each of the operating points comprises a predetermined set of values of a supply voltage and a supply current. For example, a first operating point comprises a first predetermined set of values of a supply voltage and a supply current to the power amplifier 204 and a second operating point comprises a second predetermined set of values of the supply voltage and the supply current to the power amplifier 204. In some exemplary embodiments, each of the operating points comprises an on/off control of the power amplifier 204.

In the exemplary embodiment, the memory component 222 may also store one or more phase shifter values corresponding to beam scanning angles for the one or more transmission elements e.g. 202. The memory component 222 may also store one or more gain settings/values corresponding to beam scanning angles for the power amplifiers of the one or more transmission elements e.g. 202.

In use, a desired beam scanning angle for the one or more transmission elements e.g. 202 is communicated to the system processing module 216. The desired beam scanning angle may be based on a system transmission requirement, or a user requirement, or a periodic transmission requirement etc. The system processing module 216 also processes a RF signal/message and transmits the RF signal to the one or more transmission elements e.g. 202 for beamforming transmission.

The system processing module 216 determines one or more phase shifter values corresponding to the desired beam scanning angle for the one or more transmission elements e.g. 202. For example, the one or more phase shifter values may be retrieved from the memory component 222 based on the desired beam scanning angle. The system processing module 216 may also determine one or more gain values for the one or more transmission elements e.g. 202. For example, the one or more gain values may be retrieved from the memory component 222 based on the desired beam scanning angle.

The system processing module 216 also retrieves one or more settings corresponding to the desired beam scanning angle. For example, the one or more settings may be retrieved from the memory component 222 based on the desired beam scanning angle. The one or more settings includes an operating point for at least one power amplifier (compare power amplifier 204) of the one or more transmission elements e.g. 202. The system processing module 216 obtains a present output power of the power amplifiers (compare power amplifier 204) from the power detectors (compare power detector 208). Thus, the system processing module 216 determines the output power and/or gain of the one or more transmission elements e.g. 202 based on the desired beam scanning angle. The system processing module 216 may then instruct a power controller (compare power controller 210) to control an output power of the at least one power amplifier (compare power amplifier 204) based on the operating point and/or the determined one or more gain values.

Thus, if the detected present output power level is not optimum for the desired beam scanning angle, the system processing module 216 adjusts the at least one power amplifier (compare power amplifier 204) based on the operating point to obtain a desired output power and/or spectral efficiency for the one or more transmission elements e.g. 202. There is therefore provided an adaptive closed loop control in controlling the output power of the one or more transmission elements e.g. 202 based on the desired beam scanning angle and based on the present output power of the power amplifiers of the one or more transmission elements e.g. 202.

At the same time or thereafter of the adapting of the output power, the system processing module 216 forwards the desired beam scanning angle, the one or more phase shifter values and the one or more gain values to the at least one transmission element controller (compare transmission element controller 218) of the one or more transmission elements e.g. 202. The at least one transmission element controller may program/set its phase shifter and gain adjustment member (compare phase shifter and gain adjustment member 220) using the received one or more phase shifter values and the one or more gain values, to set the beamforming or beam scanning angle at the antennas (compare antenna 206).

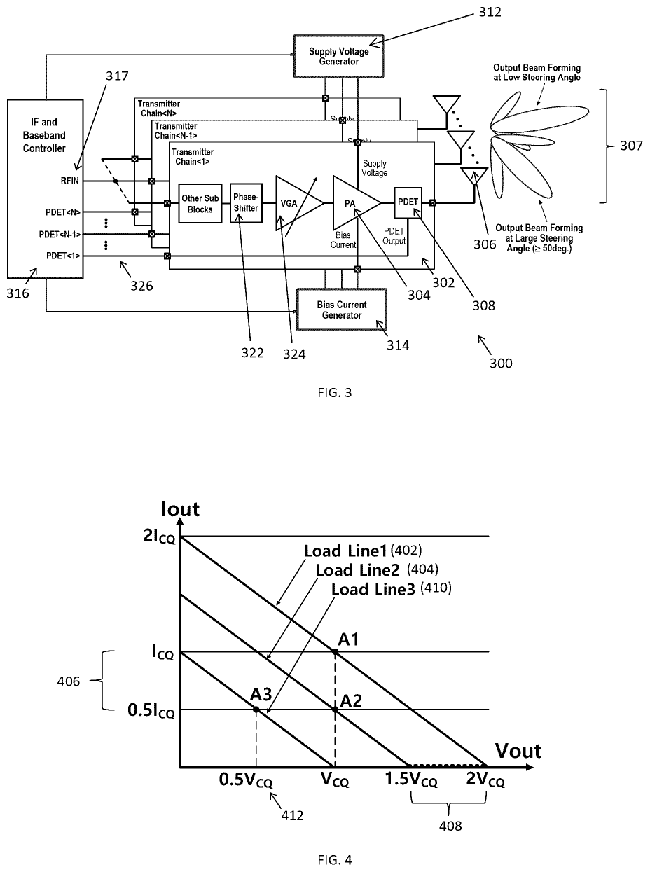

FIG. 3 is a schematic diagram of a beamforming transmission system in another exemplary embodiment. The beamforming transmission system 300 functions substantially similarly to the transmission system 200 described with reference to FIG. 2. Some components are not included in the diagram for simplicity and it will be appreciated that the description with respect to the transmission system 200 including the workings/functions of the transmission system 200 apply to the transmission system 300.

The transmission system 300 comprises one or more transmission elements e.g. 302. In the exemplary embodiment, the one or more transmission elements e.g. 302 are in the form of beamforming arrays. Each of the one or more transmission elements e.g. 302 comprises a power amplifier 304, an antenna 306 coupled to the power amplifier 304 and a power detector 308 coupled to the antenna 306. The antenna 306 is used for beamforming at its output. See e.g. numeral 307.

The transmission system 300 also comprises a power controller coupled to the power amplifier 304. In the exemplary embodiment, the power controller is implemented in the form of, or comprises, a supply voltage generator 312 and a bias current generator 314.

The transmission system 300 further comprises a system processing module 316 that is coupled to the supply voltage generator 312 and the bias current generator 314. The system processing module 316 is in the form of an Intermediate Frequency (IF) and Baseband controller or a microcontroller unit (MCU). The IF and Baseband controller 316 is also coupled to the one or more transmission elements e.g. 302. The IF and Baseband controller 316 is arranged to transmit RF signals/messages (see RFIN port 317) to the one or more transmission elements e.g. 302 for beamforming transmission.

In the exemplary embodiment, the IF and Baseband controller 316 is capable of, and is arranged to, instructing/instruct the supply voltage generator 312 and the bias current generator 314 to control an output power of the power amplifier 304. To control the output power of the power amplifier 304, the IF and Baseband controller 316 is arranged to determine a desired beam scanning angle of the one or more transmission elements e.g. 302 and to also obtain a present/current output power of the power amplifier 304 from the power detector 308. The feedback 326 from the power detector 308 is schematically shown. Compare also the receiving ports at the IF and Baseband controller 316 (e.g. PDET<N>, where there are N number of transmission elements e.g. 302). Based on both the desired beam scanning angle and the present output power of the power amplifier 304, the IF and Baseband controller 316 is capable of instructing, or is arranged to instruct, the supply voltage generator 312 and the bias current generator 314 to control the output power of the power amplifier 304.

In the exemplary embodiment, there is provided an adaptive closed loop control on the power amplifier 304 output power by the IF and Baseband controller 316 in determining a desired beam scanning angle of the one or more transmission elements e.g. 302 and in obtaining a present/current output power of the power amplifiers e.g. the power amplifier 304. Based on the present/current output power of the power amplifier 304 (as the feedback 326), depending on the desired beam scanning angle, the IF and Baseband controller 316 can simultaneously adjust or control the supply voltage and bias current to the power amplifier 304. In the exemplary embodiment, the supply voltage and bias current to the power amplifiers e.g. 304 of the one or more transmission elements e.g. 302 are also simultaneously adjustable or controllable by the IF and Baseband controller 316.

The IF and Baseband controller 316 provides such simultaneous adjustment by instructing the supply voltage generator 312 (for the supply voltage) and the bias current generator 314 (for the bias current supply) to the power amplifier 304.

Further, in the exemplary embodiment, the IF and Baseband controller 316 can directly and independently adjust or control the bias current to the power amplifier 304, and to the power amplifiers e.g. 304 of the one or more transmission elements e.g. 302. For example, the bias current can be adjusted independently of the supply voltage. For example, independent control of the supply voltage and bias current can provide a larger degree of flexibility and unconnected control over the supply voltage and bias current to the power amplifier 304 that can allow the output power level of the to the power amplifier 304 to be adjustable over a wider range.

In the exemplary embodiment, each of the one or more transmission elements e.g. 302 comprises a transmission element controller (not shown for simplicity). For example, the transmission element controller may be in the form of a transmission element integrated chip (IC) or beamforming/beamformer IC. Each of the one or more transmission elements e.g. 302 also comprises a phase shifter and gain adjustment member coupled to the transmission element controller (not shown). The phase shifter and gain adjustment member is in the form of, or comprises, a phase shifter 322 and a variable gain amplifier 324. The phase shifter 322 and the variable gain amplifier 324 are coupled to the power amplifier 304 and can provide phase shifter values and gain to the power amplifier 304. The gain of the power amplifier 304 is adjustable/controllable based on the desired beam scanning angle.

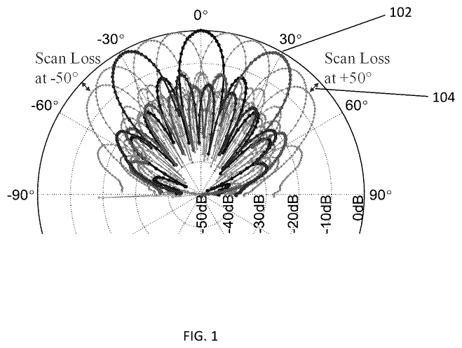

In the exemplary embodiment, the desired beam scanning angle is arranged to be set by setting at least one of the phase shifters (compare phase shifter 322) of the one or more transmission elements e.g. 302. The inventors recognize that if the beam scanning angle is greater than about 50 degrees (compare FIG. 1), the scanning loss may become larger than 5 dB due to lesser antenna gain. In such a scenario, the one or more transmission elements e.g. 302 or the beamforming elements may typically maximize their output powers (at the respective power amplifiers) to compensate for the increased scanning loss. On the other hand, if the scan angle is less than about 50 degrees (compare FIG. 1), the one or more transmission elements e.g. 302 or the beamforming elements may typically not need to operate in a high power mode or at their maximum output powers.

The inventors recognize that if bias current is reduced, e.g. in a low power mode (when high power is not needed), beamforming elements may typically show poor power efficiency in the low power mode. This may be further understood with reference to load line 2 (numeral 404) of FIG. 4. The description below of the exemplary embodiment may provide an improvement in power efficiency e.g. at a low power mode (or if high or maximum output power is not needed).

The functions of the beamforming transmission system 300 are substantially similar to the functions as described for the beamforming transmission system 200 of FIG. 2. In the description below, an operation is described for the simultaneous adjustment/control of the supply voltage generator 312 and the bias current generator 314 for the supply voltage and bias current to the power amplifiers e.g. 304 of the one or more transmission elements e.g. 302. Some functions are not repeated in the description below for simplicity.

Referring to the beamforming transmission system 300, in an operation, a desired beam scanning angle for the one or more transmission elements e.g. 302 is communicated to the system processing module 316. The system processing module 316 retrieves one or more settings corresponding to the desired beam scanning angle. For example, the one or more settings may be retrieved from a memory component (compare memory component 222 of FIG. 2) based on the desired beam scanning angle. The one or more settings includes an operating point for at least one power amplifier (compare power amplifier 304) of the one or more transmission elements e.g. 302. The operating point comprises a predetermined set of values of a supply voltage and a supply current to the at least one power amplifier (compare power amplifier 304). Predetermined sets of values of a supply voltage and a supply current are stored in the memory component and are based on beam steering/scanning angles and output power levels. Thus, the system processing module 316 determines the output power and/or gain of the one or more transmission elements e.g. 302 based on the desired beam scanning angle.

The system processing module 316 obtains a present output power of the power amplifiers (compare power amplifier 304) from the power detectors (compare power detector 308). The system processing module 316 may then instruct adjustment/control of the output power of the at least one power amplifier (compare power amplifier 304) based on a simultaneous adjustment of a supply voltage and a bias current to the at least one power amplifier (compare power amplifier 304), and to the power amplifiers of the one or more transmission elements e.g. 302. In the exemplary embodiment, the system processing module 316 controls/adjusts the supply voltage generator 312 and the bias current generator 314 using the retrieved operating point (i.e. using the predetermined set of values of a supply voltage and a supply current) to provide the supply voltage and bias current to the at least one power amplifier (compare power amplifier 304).

For example, in one scenario if the desired beam scanning angle is about 50 degrees or more than about 50 degrees, an operating point is determined/retrieved based on the desired beam scanning angle. Based on the operating point and based on a detected present/current output power of the one or more transmission elements e.g. 302, the system processing module 316 controls/adjusts the supply voltage generator 312 and the bias current generator 314 so that the supply voltage and bias current provided to the at least one power amplifier (compare power amplifier 304) may adjust/control the output power of the at least one power amplifier (compare power amplifier 304) to be near or at a maximum power level (i.e. based on the desired beam scanning angle). For example, the at least one power amplifier (compare power amplifier 304) is controlled to produce a high/maximum power output level. For example, the one or more transmission elements e.g. 302 may operate in a high power mode. As an example, operating point A1 with reference to FIG. 4 may be the operating point for a high power mode.

For example, in another scenario if the desired beam scanning angle is less than about 50 degrees, another operating point is determined/retrieved based on the desired beam scanning angle. Based on the another operating point and based on a detected present/current output power of the one or more transmission elements e.g. 302, the system processing module 316 controls/adjusts the supply voltage generator 312 and the bias current generator 314 so that the supply voltage and bias current provided to the at least one power amplifier (compare power amplifier 304) may adjust/control the output power of the at least one power amplifier (compare power amplifier 304) to be at a lower power level than a maximum/high power level (i.e. based on the desired beam scanning angle). For example, the at least one power amplifier (compare power amplifier 304) is controlled to produce a lower power output level. For example, the one or more transmission elements e.g. 302 may operate in a low power mode thus achieving a high power efficiency (with a lower output power). As an example, operating point A3 with reference to FIG. 4 may be the operating point for a low power mode.

In the exemplary embodiment, the bias current to the at least one power amplifier (compare power amplifier 304) can be adjusted directly and independently of the supply voltage, i.e. via control/adjustment of the bias current generator 314.

In the exemplary embodiment, the supply voltage generator 312 may be implemented in a variety of ways. For example, the supply voltage generator 312 may comprise a DC-DC converter, a LDO (low-dropout regulator), or both.

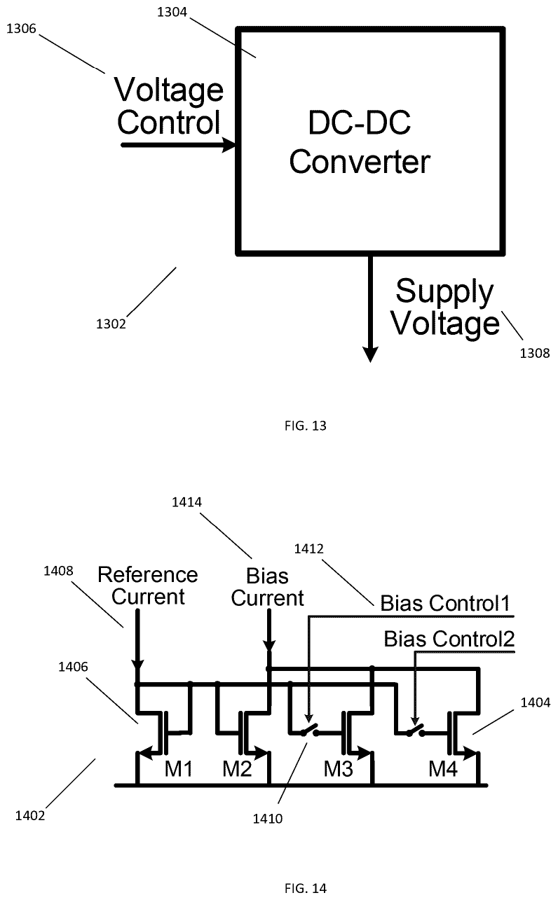

FIG. 13 shows an example of a supply voltage generator. A supply voltage generator 1302 comprises a DC-DC converter 1304. The supply voltage generator 1302 may be an example implementation of the supply voltage generator 312 (FIG. 3). In FIG. 13, a voltage control signal 1306 is used as an input to the DC-DC converter 1304 to control an output of the DC-DC converter 1304 as a supply voltage 1308. The voltage control signal 1306 may be provided by a system processing module (compare system processing module 316 of FIG. 3). The supply voltage 1308 can therefore be variable and controllable.

In the exemplary embodiment, the bias current generator 314 may be implemented in a variety of ways. For example, the bias current generator 314 may comprise an array of current sources with switches for selection(s), and/or a DAC (digital to analogue converter). For example, the bias current generator 314 may be based on one or more current mirror circuits, and a current mirroring ratio of the one or more current mirror circuits can be varied by using one or more switches in the one or more current mirror circuits.

FIG. 14 shows an example of a bias current generator. A bias current generator 1402 may be an example implementation of the bias current generator 314 (FIG. 3). The bias current generator 1402 comprises a plurality of transistors e.g. 1404. For example, the plurality of transistors e.g. 1404 may be field effect transistors (FETs). In the example, the plurality of transistors e.g. 1404 (M1 to M4) are tied at their gates. A first transistor M1 1406 is provided with a reference current 1408 at its drain that is in turn coupled to its gate, the reference current 1408 being provided e.g. by way of a voltage signal. At least one transistor is provided with a bias control signal at its gate. In the example, two transistors M3 and M4 e.g. 1404 are each provided with a respective switch e.g. 1410 controllable by a respective bias control signal (Bias Control1 and Bias Control2) e.g. 1412. The bias control signals may be provided by a system processing module (compare system processing module 316 of FIG. 3). In the example, the bias current 1414 from the bias current generator 1402 can be controlled by the bias control signals e.g. 1412, i.e. with the opening and/or closing of the switches e.g. 1410 to allow lesser or more current flow. The bias current 1414 can therefore be variable and controllable.

FIG. 4 is a schematic drawing to illustrate load lines for a power amplifier in a beamforming array. Iout and Vout represent the output current and output voltage respectively of the power amplifier. A1, A2 and A3 denote operating points for the power amplifier in terms of the supply voltage and bias current.

For load line 1 (numeral 402), it can be observed that the operating point A1 is appropriate/suitable for a high power mode because the largest output voltage and output current swings can be obtained along the load line, i.e. as much as 2V_{CQ} and 2I_{CQ}, respectively. At the operating point A1, the supply voltage can be V_{cq} and the supply or bias current can be I_{cq}. As an example, the operating point A1 may be the operating point for the high power mode or high or maximum power level described with reference to FIG. 3.

To switch to a low power mode, conventionally, the bias current is typically reduced. This may be observed at load line 2 (numeral 404). For load line 2 (numeral 404), A2 is considered as the operating point in a low power mode. In this illustration, as the inventors recognize, conventionally, the bias current is decreased from I_{CQ} to 0.5I_{CQ} (see numeral 406) and the voltage swing is limited below 1.5V_{CQ} (see numeral 408) for the same given supply voltage of V_{CQ}, i.e. unchanged voltage supply from the high power mode for load line 1 (numeral 402).

Using the transmission system 300 of FIG. 3, the inventors recognize that it is possible to achieve better efficiency in simultaneously and independently adjusting/controlling the supply voltage and bias current to the power amplifier. The operating point A3 of the load line 3 (numeral 410) is an example of simultaneous control on the supply voltage and bias current. The supply voltage may be lowered to 0.5Vcq (numeral 412) and the supply current may be lowered to 0.5I_{CQ} which is the same level as that for load line 2 (404). Thus, for load line 3 (410), the output voltage and output current can provide the maximum swings for the given supply voltage and bias current, and it is observed that there is beneficially no waste of power supply voltage and bias current. As such, a better efficiency and better conservation of power supply voltage and bias current may be achieved. As an example, the operating point A3 may be the another operating point for the low power mode or lower power level described with reference to FIG. 3.

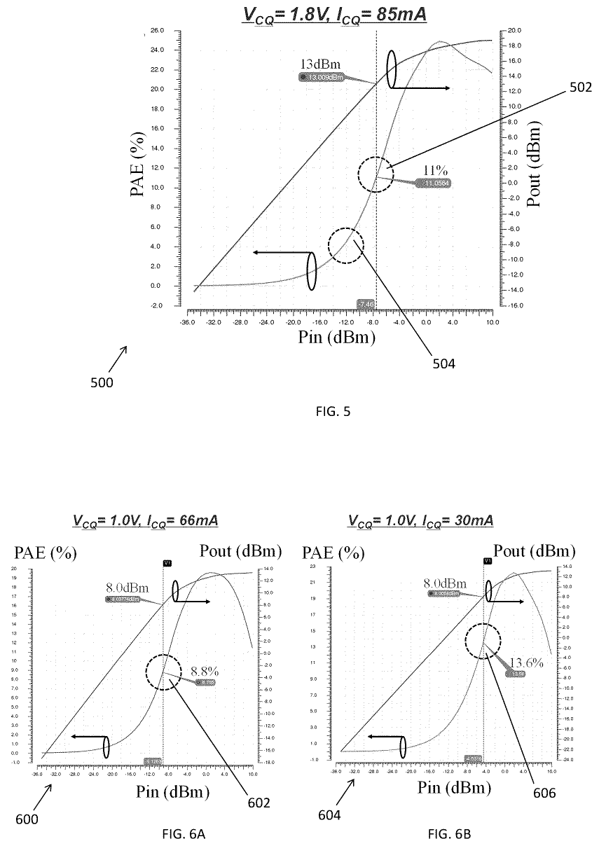

FIG. 5 is a graph showing simulated results of power-added efficiency (PAE) and output power (Pout) of a power amplifier to show a drop in efficiency if an operating point of the power amplifier is not adjusted. The graph 500 is for an operating point of supply voltage V_{CQ}=1.8V and supply bias current I_{CQ}=85 mA for the power amplifier. From the graph 500, at Pout of 13 dBm which can be considered as the maximum power available in a high power mode, PAE is observed to be 11% (see numeral 502). If Pout is reduced to 8 dBm, it can be observed that PAE is lowered to about 5% (see numeral 504). As such, it can be recognised that if the operating point is not adjusted, at a lower power mode (e.g. at 8 dBm), the PAE is low.

FIG. 6A is a graph showing simulated results of power-added efficiency (PAE) and output power (Pout) of the power amplifier of FIG. 5 with a first different operating point in an exemplary embodiment. In FIG. 6A, the graph 600 is for supply voltage V_{CQ}=1.0V and supply bias current I_{CQ}=66 mA for the power amplifier, i.e. as the first different operating point of the exemplary embodiment. As such, both the supply voltage and the bias current have been simultaneously and independently adjusted from the operating point of FIG. 5. That is, V_{CQ} and I_{CQ} are reduced to 1.0V and 66 mA respectively. At a lowered Pout of 8 dBm, PAE is observed to be 8.8% (see numeral 602). Thus, PAE has improved from 5% (observed at FIGS. 5) to 8.8%.

FIG. 6B is a graph showing simulated results of power-added efficiency (PAE) and output power (Pout) of the power amplifier of FIG. 5 with a second different operating point in an exemplary embodiment. In FIG. 6B, the graph 604 is for supply voltage V_{CQ}=1.0V and supply bias current I_{CQ}=30 mA for the power amplifier, i.e. as the second different operating point of the exemplary embodiment. As such, both the supply voltage and the bias current have been simultaneously and independently adjusted from the operating point of FIG. 5. That is, V_{CQ} and I_{CQ} are reduced to 1.0V and 33 mA respectively. As compared to FIG. 6A, I_{CQ} is further reduced to 30 mA. At a lowered Pout of 8 dBm, PAE is observed to be 13.6% (see numeral 606). Thus, PAE has improved from 5% (observed at FIGS. 5) to 13.6%.

From the graphs 600, 604, the inventors have verified that with a simultaneous and independent adjustment of the supply voltage and the bias current to the power amplifier, with a low or lower power mode (or when not needing maximum power), PAE can be significantly improved. Further, from the graphs 600, 604, it should be noted that the power amplifier stays in the operating region before output power saturation and the increase of PAE is not due to the power saturation.

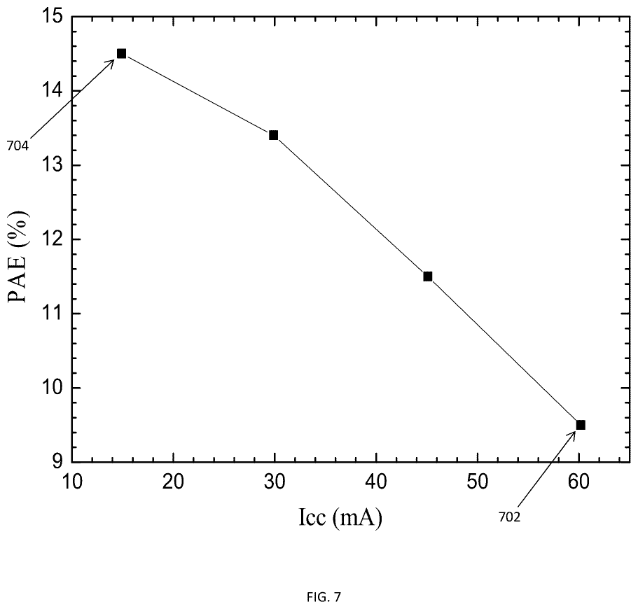

FIG. 7 is a graph for illustrating a change in power-added efficiency (PAE) of a power amplifier with respect to a change in a supply bias current to the power amplifier at a fixed output power in an exemplary embodiment. It is observed that, for a fixed output power of Pout=8 dBm (e.g. when high power is not needed) and a constant supply voltage of V_{cc} or V_{cq}=1.0V, decreasing the supply bias current can beneficially improve the PAE of the power amplifier. For example, at point 702, with I_{CQ}=60 mA, the PAE is about 8.8% while at point 704, with I_{CQ}=15 mA, the PAE is about 14.5%.

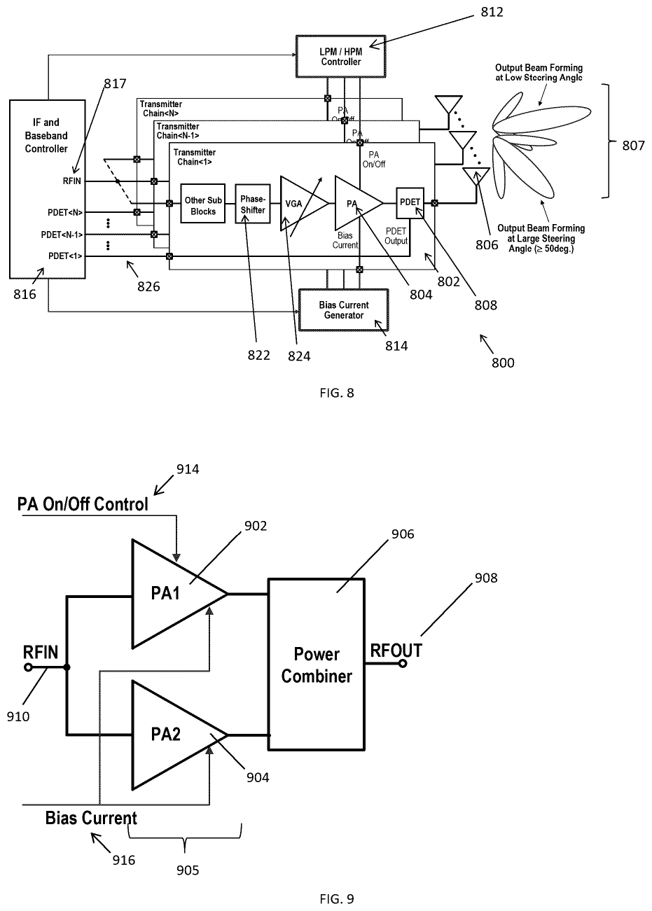

FIG. 8 is a schematic diagram of a beamforming transmission system in another exemplary embodiment. The beamforming transmission system 800 functions substantially similarly to the transmission system 200 described with reference to FIG. 2. Some components are not included in the diagram for simplicity and it will be appreciated that the description with respect to the transmission system 200 including the workings/functions of the transmission system 200 apply to the transmission system 800.

The transmission system 800 comprises one or more transmission elements e.g. 802. In the exemplary embodiment, the one or more transmission elements e.g. 802 are in the form of beamforming arrays. Each of the one or more transmission elements e.g. 802 comprises a power amplifier 804, an antenna 806 coupled to the power amplifier 804 and a power detector 808 coupled to the antenna 806. The antenna 806 is used for beamforming at its output. See e.g. numeral 807.

The transmission system 800 also comprises a power controller coupled to the power amplifier 804. In the exemplary embodiment, the power controller is implemented in the form of, or comprises, a power mode controller 812 and a bias current generator 814.

The transmission system 800 further comprises a system processing module 816 that is coupled to the power mode controller 812 and the bias current generator 814. The system processing module 816 is in the form of an Intermediate Frequency (IF) and Baseband controller or a microcontroller unit (MCU). The IF and Baseband controller 816 is also coupled to the one or more transmission elements e.g. 802. The IF and Baseband controller 816 is arranged to transmit RF signals/messages (see RFIN port 817) to the one or more transmission elements e.g. 302 for beamforming transmission.

In the exemplary embodiment, the IF and Baseband controller 816 is capable of, and is arranged to, instructing/instruct the power mode controller 812 and the bias current generator 814 to control an output power of the power amplifier 804, and thus, the overall output power of the one or more transmission elements e.g. 802. To control the output power of the one or more transmission elements e.g. 802, the IF and Baseband controller 816 is arranged to determine a desired beam scanning angle of the one or more transmission elements e.g. 802 and to also obtain a present/current output power of the one or more transmission elements e.g. 802, e.g. obtaining a present/current output power of the power amplifier 804 from the power detector 808 (as an example of one of the transmission elements e.g. 802). The feedback 826 from the power detector 808 is schematically shown. Compare also the receiving ports at the IF and Baseband controller 816 (e.g. PDET<N>, where there are N number of transmission elements e.g. 802). Based on both the desired beam scanning angle and the present output power of the power amplifier 804 (as an example of one of the transmission elements e.g. 802), the IF and Baseband controller 816 is capable of instructing, or is arranged to instruct, the power mode controller 812 and the bias current generator 814 to control the output power of the one or more transmission elements e.g. 802, by controlling the output power of the power amplifier 804 (as an example of one of the transmission elements e.g. 802).

In the exemplary embodiment, there is provided an adaptive closed loop control on the power amplifier 804 output power by the IF and Baseband controller 816 in determining a desired beam scanning angle of the one or more transmission elements e.g. 802 and in obtaining a present/current output power of the power amplifiers e.g. 804 of the one of the transmission elements e.g. 802. Based on the present/current output power of the power amplifiers e.g. 804 (see the feedback 826), depending on the desired beam scanning/steering angle(s), the IF and Baseband controller 816 can choose/select a suitable operation mode of the one or more transmission elements e.g. 802. Thus, there is an adaptive closed loop control on the operation modes of the one or more transmission elements e.g. 802.

In the exemplary embodiment, the operation mode is based on a low power mode (LPM) and a high power mode (HPM). The power mode controller 812 may be termed as a LPM/HPM controller 812. By choosing a suitable operation mode of the one or more transmission elements e.g. 802, the power efficiency of the one or more transmission elements e.g. 802 may be maintained in high efficiency.

In a low power mode, the one or more transmission elements e.g. 802 (via control of e.g. the power amplifier 804) may be optimised to operate at a high efficiency with a lower output power than if the one or more transmission elements e.g. 802 (via control of e.g. the power amplifier 804) is operating at its maximum power (in a high or a maximum power mode), if high or maximum power is not required. For example, at beam scanning angles of 30 degrees, the power amplifier 804 may be controlled such that the one or more transmission elements e.g. 802 operates in a low power mode. Further, in the exemplary embodiment, the bias current or supply current to the power amplifier 804 may also be adjusted/controlled in both the low power mode and high power mode via the bias current generator 814.

In the exemplary embodiment, each of the one or more transmission elements e.g. 802 comprises a transmission element controller (not shown for simplicity). For example, the transmission element controller may be in the form of a transmission element integrated chip (IC) or beamforming/beamformer IC. Each of the one or more transmission elements e.g. 802 also comprises a phase shifter and gain adjustment member coupled to the transmission element controller (not shown). The phase shifter and gain adjustment member is in the form of, or comprises, a phase shifter 822 and a variable gain amplifier 824. The phase shifter 822 and the variable gain amplifier 824 are coupled to the power amplifier 804 and can provide phase shifter values and gain to the power amplifier 804. The gain of the power amplifier 804 is adjustable/controllable based on the desired beam scanning angle.

The functions of the beamforming transmission system 800 are substantially similar to the functions as described for the beamforming transmission system 200 of FIG. 2. In the description below, an operation is described for output power control of the beamforming transmission system 800 based on the on/off control provided by the power mode controller 812. Some functions are not repeated in the description below for simplicity.

Referring to the beamforming transmission system 800, in an operation, a desired beam scanning angle for the one or more transmission elements e.g. 802 is communicated to the system processing module 816. The system processing module 816 retrieves one or more settings corresponding to the desired beam scanning angle. For example, the one or more settings may be retrieved from a memory component (compare memory component 222 of FIG. 2) based on the desired beam scanning angle. The one or more settings includes an operating point for at least one power amplifier (compare power amplifier 804) of the one or more transmission elements e.g. 802. The operating point comprises an on/off control of the at least one power amplifier (compare power amplifier 804). Operating points are stored in the memory component and are based on beam steering/scanning angles and output power levels. Thus, the system processing module 816 determines the output power and/or gain of the one or more transmission elements e.g. 802 based on the desired beam scanning angle. In some exemplary embodiments, the operating point may also comprise a predetermined set of values of a supply voltage and a supply current to the at least one power amplifier (compare power amplifier 804).

The system processing module 816 obtains a present output power of the power amplifiers (compare power amplifier 804) from the power detectors (compare power detector 808). The system processing module 816 may then instruct adjustment/control of the output power of the at least one power amplifier (compare power amplifier 804) based on using at least one of the LPM/HPM controller 812 and the bias current generator 814. In the exemplary embodiment, the system processing module 816 controls the LPM/HPM controller 812 and the bias current generator 814 using the retrieved operating point (i.e. using the on/of control, and in some exemplary embodiments, a predetermined set of values of a supply voltage and a supply current) to control the at least one power amplifier (compare power amplifier 804).

For example, in one scenario if the desired beam scanning angle is about 50 degrees or more than about 50 degrees, an operating point is determined/retrieved based on the desired beam scanning angle. Based on the operating point and based on a detected present/current output power of the one or more transmission elements e.g. 802, the system processing module 816 turns/switches on two or more power amplifiers (compare power amplifier 804) using the LPM/HPM controller 812. The output power of the turned on power amplifiers are combined, e.g. using a power combiner, to provide the output power of the one or more transmission elements e.g. 802. For example, for a high power mode, the system processing module 816 operates/controls the at least one power amplifier (compare power amplifier 804) in a high power mode, wherein the output power of the two or more turned on power amplifiers are combined to operate near or at a maximum power level combined of the two or more turned on power amplifiers.

For example, in another scenario if the desired beam scanning angle is less than about 50 degrees, another operating point is determined/retrieved based on the desired beam scanning angle. Based on the another operating point and based on a detected present/current output power of the one or more transmission elements e.g. 802, the system processing module 816 controls/adjusts an on/off control of the at least one power amplifier (compare power amplifier 804) using the LPM/HPM controller 812 such that the one or more transmission elements e.g. 802 operates at a lower power level (or output power) than a maximum/high power level (i.e. based on the desired beam scanning angle. For example, the on/off control may be adjusted to turn off the at least one power amplifier (compare power amplifier 804). For example, for a low power mode, the at least one power amplifier (compare power amplifier 804) is controlled to produce a lower power output level for the one or more transmission elements e.g. 802. The one or more transmission elements e.g. 802 may operate in a low power mode thus achieving a high power efficiency, e.g. as compared to operating at the maximum output power of the one or more transmission elements e.g. 802.

Therefore, with the above examples, the system processing module 816 is arranged to switch on or off the power amplifier 804 based on an operating point (one of the above operating point and the another operating point) of the power amplifier. In the exemplary embodiment, the system processing module 816 is provided with the ability to select/choose each of the power amplifiers, e.g. 804 to turn on or off. The instruction for the system processing module 816 to select which one or more or none of the power amplifiers, e.g. 804 to turn off is based on an operating point determined/retrieved based on a desired beam scanning angle.

In the exemplary embodiment, the power mode controller 812 may be implemented in the form of one or more switches coupled to each of the power amplifiers e.g. 804 of the one or more transmission elements e.g. 802. For example, the one or more switches may be one or more digital switches. The one or more switches may be used to control a supply of a voltage and/or a bias current to each of the power amplifiers e.g. 804. As such, the switch on or off of the power amplifier 804 is independent of at least one other power amplifier of the one or more transmission elements e.g. 802.

In an example, to adjust the on/off control of the power amplifier 804, if the power amplifier 804 is to be turned off, the operating point may comprise an instruction to the system processing module 816 to turn off a switch to supply a voltage and/or a bias current to the power amplifier 804.

In another example, to adjust the on/off control of the power amplifier 804, if the power amplifier 804 is to be turned off, the predetermined set of values of a supply voltage and a supply current may comprise a zero supply voltage and/or a zero bias current for the power amplifier 804 such that an instruction may be transmitted to the system processing module 816 to turn off a voltage and/or a bias current to the power amplifier 804. It will be appreciated that there may be other ways to implement the on/off control.

In the exemplary embodiment, the bias current to the at least one power amplifier (compare power amplifier 804) can be adjusted directly, i.e. via control/adjustment of the bias current generator 814. For example, the bias current may be adjusted by the bias current generator 814 in both a low power mode and a high power mode. The at least one power amplifier (compare power amplifier 804) can therefore be adjusted to operate at a high efficiency at a lower output power. Compare FIG. 4. The bias current generator 814 may be implemented as exemplarily described at FIG. 3.

It will be appreciated that, to control a supply voltage to the power amplifier 804, the beamforming transmission system 800 may comprise a supply voltage generator (compare supply voltage generator 312 of FIG. 3) coupled to the system processing module 816 and/or the power mode controller 812. Such a supply voltage generator (not shown) may be implemented as exemplarily described at FIG. 3.

FIG. 9 is a schematic diagram for illustrating the power controller of FIG. 8 in an exemplary embodiment. In FIG. 9, a plurality of power amplifiers, e.g. each being from a transmission element, is shown.

There is provided a first power amplifier 902 and a second power amplifier 904. Each of the first power amplifier 902 and the second power amplifier 904 are substantially identical to the power amplifier 804 of FIG. 8. A power combiner 906 is provided coupled to the respective outputs of the first power amplifier 902 and the second power amplifier 904 to provide a signal output (or beamforming output) 908 of a plurality or array of transmission elements (compare the one or more transmission elements e.g. 802 of FIG. 8). As such, the first power amplifier 902 and the second power amplifier 904 may collectively be viewed as a power-combined power amplifier 905.

An RF input 910 is provided for input of signals to the first power amplifier 902 and the second power amplifier 904 for the beamforming at the signal output 908. The RF input 910 is coupled to and provided by a system processing module (compare system processing module 216 of FIG. 2).

In the exemplary embodiment, an on/off control 914 is coupled to at least one of the first power amplifier 902 and the second power amplifier 904. The on/off control 914 is provided by a power mode controller (compare power mode controller 812 of FIG. 8). A bias current supply 916 is coupled to the first power amplifier 902 and the second power amplifier 904. The bias current supply 916 is provided by a bias current generator (compare bias current generator 814 of FIG. 8). The on/off control 914 and the bias current supply 916 may be controlled by the system processing module (compare system processing module 216 of FIG. 2).

In the exemplary embodiment, the on/off control 914 may control whether both the first power amplifier 902 and the second power amplifier 904 are operating or whether only one of the first power amplifier 902 and the second power amplifier 904 is operating. In a high power mode for the transmission elements (compare the one or more transmission elements e.g. 802 of FIG. 8), the first power amplifier 902 and the second power amplifier 904 are controlled to be both operating. In the high power mode for the transmission elements (compare the one or more transmission elements e.g. 802 of FIG. 8), the power combiner 906 combines the output powers of the first power amplifier 902 and the second power amplifier 904. In a low power mode, for example the first power amplifier 902 may be controlled to be not operating (i.e. powered off or switched off or turned off) while the second power amplifier 904 is operating alone/solely.

In the exemplary embodiment, there is therefore provided an adaptive closed loop control on the power-combined power amplifier 905 output power by the system processing module (compare system processing module 216 of FIG. 2) in determining a desired beam scanning angle of the one or more transmission elements and in obtaining a present/current output power of the power-combined power amplifier 905. Based on the present/current output power of the power-combined power amplifier 905, depending on the desired beam scanning angle, the system processing module can select/choose an appropriate operation mode (e.g. a low power mode or a high power mode) for high power efficiency (in both the low power mode and high power mode). In the exemplary embodiment, the system processing module chooses the operation mode by controlling the on/off control 914. The choice or selection of the on/off control is based on a setting (e.g. an operating point) determined based on desired beam scanning angle, e.g. retrieved from a memory component (compare memory component 222 of FIG. 2). In the exemplary embodiment, the on/off control 914 may for example be an instruction to turn off the first power amplifier 902.

In addition, in a low power mode, if the second power amplifier 904 is operating only, the system processing module can control the bias current supply 916 to the second power amplifier 904 such that the second power amplifier 904 is optimised to operate at a high efficiency with a lower output power as compared to its maximum output power in the high power mode. For example, the bias current to the second power amplifier 904 may be lowered such that the second power amplifier 904 can still fulfil/provide the output power for beamforming at the desired beam scanning angle in the low power mode (i.e. no need for its maximum output power).

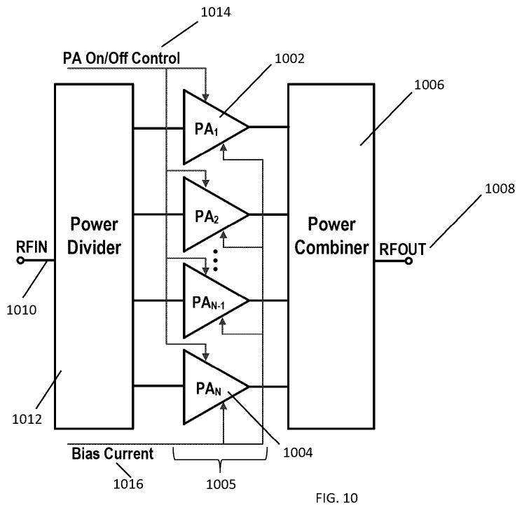

FIG. 10 is a schematic diagram for illustrating the power controller of FIG. 8 in another exemplary embodiment. In FIG. 10, more than two power amplifiers, e.g. each being from a transmission element, are shown. FIG. 10 is provided to show a power-combined N-number of power amplifiers (with N more than 2) and is an extension of FIG. 9 (i.e. functions similarly to FIG. 9 but with more power amplifiers and thus, a larger degree of control).

There is provided a plurality of power amplifiers e.g. 1002, 1004. Each of the power amplifiers e.g. 1002, 1004 are substantially identical to the power amplifier 804 of FIG. 8. A power combiner 1006 is provided coupled to the respective outputs of the power amplifiers e.g. 1002, 1004 to provide a signal output (or beamforming output) 1008 of a plurality or array of transmission elements (compare the one or more transmission elements e.g. 802 of FIG. 8). As such, the power amplifiers e.g. 1002, 1004 may collectively be viewed as a power-combined power amplifier 1005. Thus, there is provided a power-combined plural power amplifier structure.

An RF input 1010 is provided for input of signals to a power divider 1012. The power divider 1012 is provided at the input side of the power amplifiers e.g. 1002, 1004 to distribute the input RF power to the plurality of power amplifiers e.g. 1002, 1004 in the power-combined plural power amplifier structure or the power-combined power amplifier 1005. The power amplifiers e.g. 1002, 1004 receive the RF input for the beamforming at the signal output 1008. The RF input 1010 is coupled to and provided by a system processing module (compare system processing module 216 of FIG. 2).

In the exemplary embodiment, an on/off control 1014 is coupled to at least one of the plurality of power amplifiers e.g. 1002, 1004. In the exemplary embodiment, the on/off control 1014 is shown coupled to all of the plurality of power amplifiers e.g. 1002, 1004. The on/off control 1014 is provided by a power mode controller (compare power mode controller 812 of FIG. 8). A bias current supply 1016 is coupled to the plurality of power amplifiers e.g. 1002, 1004. The bias current supply 1016 is provided by a bias current generator (compare bias current generator 814 of FIG. 8). The on/off control 1014 and the bias current supply 1016 may be controlled by the system processing module (compare system processing module 216 of FIG. 2).

In the exemplary embodiment, the on/off control 1014 may control the number of power amplifiers that are operating within the power-combined plural power amplifier structure. For example, there may be one power amplifier e.g. 1002, 1004 operating based on the on/off control 1014 or there may be more than one power amplifier e.g. 1002, 1004 operating based on the on/off control 1014. For example, if it is determined by the system processing module that more output power should be provided for beamforming for a desired beam scanning angle of the one or more transmission elements, the system processing module can control the on/off control 1014 to turn on more power amplifiers e.g. 1002, 1004 to maintain high power efficiency in a gradual manner. When more than one power amplifier e.g. 1002, 1004 is operating, the power combiner 1006 combines the output powers of the power amplifiers e.g. 1002, 1004 that are operating.

In the exemplary embodiment, there is therefore provided an adaptive closed loop control on the power-combined power amplifier 1005 output power by the system processing module (compare system processing module 216 of FIG. 2) in determining a desired beam scanning angle of the one or more transmission elements and in obtaining a present/current output power of the power-combined power amplifier 1005. Based on the present/current output power of the power-combined power amplifier 1005, depending on the desired beam scanning angle, the system processing module can select/choose an appropriate operation mode (e.g. a low power mode or a high power mode) for high power efficiency (in both the low power mode and high power mode). In the exemplary embodiment, the system processing module chooses the operation mode by controlling the on/off control 1014. Furthermore, the system processing module may choose the number of power amplifiers e.g. 1002, 1004 to be turned on. The choice or selection of the on/off control is based on a setting (e.g. an operating point) determined based on desired beam scanning angle, e.g. retrieved from a memory component (compare memory component 222 of FIG. 2). In the exemplary embodiment, the on/off control 1014 may for example be an instruction to turn off one or more or none of the power amplifiers, e.g. 1002, 1004.

In addition, the system processing module can control the bias current supply 1016 to the power amplifiers e.g. 1002, 1004 that are turned on such that these turned on power amplifiers e.g. 1002, 1004 are optimised to operate at a high efficiency with a lower output power as compared to their combined maximum output power.

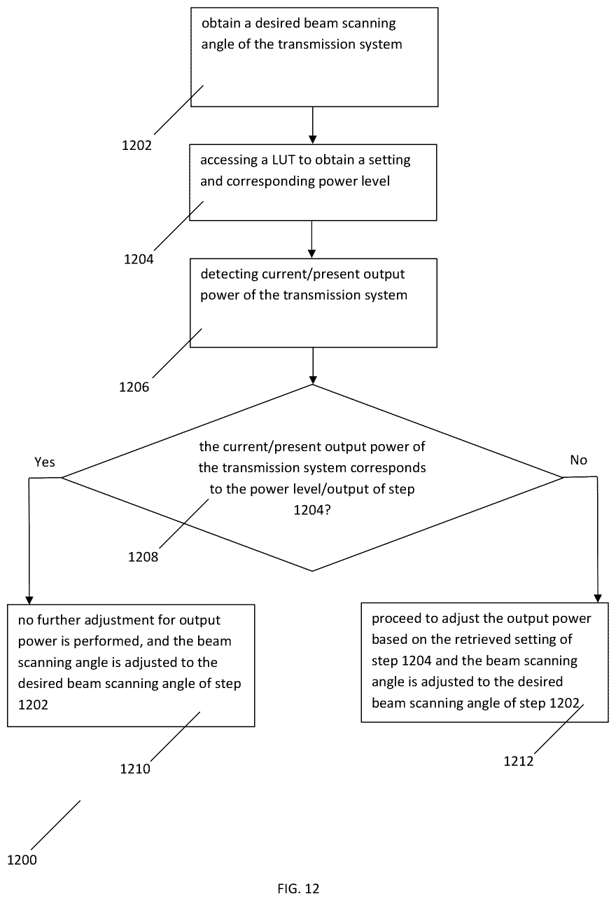

FIG. 12 is a schematic flowchart 1200 for illustrating an exemplary decision process for controlling an output power of a beamforming transmission system. At step 1202, a desired beam scanning angle of the transmission system is obtained. The desired beam scanning angle may be transmitted or communicated to the transmission system. For example, a system processing module of the transmission system is arranged to determine a desired beam scanning angle, e.g. from a user. At step 1204, a Look-Up Table (LUT) is accessed to obtain a setting and corresponding power level, corresponding to the desired beam scanning angle of the transmission system. For example, the setting comprises a voltage value and a current value for simultaneous control of a power amplifier of the transmission system. For another example, the setting comprises instructions to turn on or turn off one or more power amplifiers of the transmission system, for example the setting may be coupled with identification of the power amplifiers to be controlled e.g. Nth amplifier and (N−1) th amplifier. For another example, the setting comprises a current value to control/adjust the bias current to one or more power amplifiers, for example the setting may be coupled with identification of the power amplifiers to be controlled e.g. Nth amplifier and (N−1) th amplifier. The corresponding power level may be a low/high power level/output e.g. with a certain tolerance.

At step 1206, a current/present output power of the transmission system is detected. For example, the detection may be by using one or more power detectors of the transmission system and transmitting the detection information/data to the system processing module. At step 1208, it is determined whether the current/present output power of the transmission system matches/corresponds to the power level/output retrieved at step 1204. For example, the determination may be performed by a system processing module of the transmission system. If it is determined at step 1208 that the current/present output power of the transmission system matches/corresponds to the power level/output retrieved at step 1204, at step 1210, no further adjustment for the output power of the transmission system is performed, and the beam scanning angle is adjusted to the desired beam scanning angle of step 1202. If it is determined at step 1208 that the current/present output power of the transmission system does not match/correspond to the power level/output retrieved at step 1204, at step 1212, the output power of the transmission system is adjusted based on the retrieved setting of step 1204, and the beam scanning angle is adjusted to the desired beam scanning angle of step 1202. For example, the adjustment of the output power of the transmission system may be instructed by the system processing module that is arranged to instruct a power controller of the transmission system to control the output power of one or more power amplifiers of the transmission system. As such, from the flowchart 1200, the output power of one or more power amplifiers of the transmission system is controllable based on both the desired beam scanning angle and the present output power of the one or more power amplifiers.

With reference to the decision process of FIG. 12, the inventors recognize that the overall gain and output power levels of a transmission system may be controlled by 0.5 dB. The inventors recognize that in a substantial number of scenarios, a detection/measure of the gain and output power may be performed for the adjustment of the gain and output power.

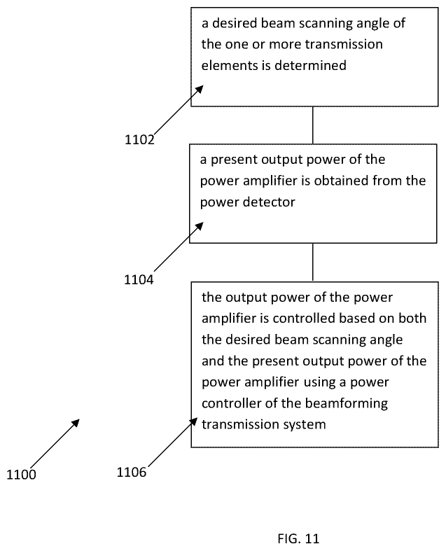

FIG. 11 is a schematic flowchart for illustrating a method of controlling an output power of a beamforming transmission system in an exemplary embodiment. The beamforming transmission system comprises one or more transmission elements, the one or more transmission elements each comprising a power amplifier; an antenna coupled to the power amplifier; and a power detector coupled to the antenna. At step 1102, a desired beam scanning angle of the one or more transmission elements is determined. At step 1104, a present output power of the power amplifier is obtained from the power detector. At step 1106, the output power of the power amplifier is controlled based on both the desired beam scanning angle and the present output power of the power amplifier using a power controller of the beamforming transmission system.

With the described exemplary embodiments, an output power control for a beamforming transmission system may be provided. In one specific exemplary embodiment, an adaptive closed loop control on a power amplifier output power is provided by simultaneously adjusting both a supply voltage and a bias current to the power amplifier based on beam steering/scanning angles. In another specific exemplary embodiment, an adaptive closed loop control to adjust a power amplifier output power or power modes of a beamforming transmission system is provided based on beam steering/scanning angles. In such an exemplary embodiment, it is possible to maintain high efficiency at a low power mode as well as a high power mode. The exemplary embodiments can improve the power and spectral efficiency for a wide range of beam steering/scanning angles including at lower power modes which may be selected at a lower beam steering angle, i.e. at an angle lesser than 50 degrees. Both power & spectral efficiency may be optimum at all beam scanning angles.

The described exemplary embodiments may be used with a phased array application with one or more RF beamforming ICs. A phased-array beamforming IC may use its maximum or high output power to compensate for a scan loss when a beamforming angle becomes larger than, for example only, 50 degrees. When the beamforming angle is moderate or low (e.g. less than about 50 degrees), the beamforming IC may use less power than its maximum or high output power (or a low power mode). As discussed in exemplary embodiments, a power supply level (or voltage supply level) and bias current may be adjusted simultaneously at a moderate or low output power level/mode or requirement so that the power efficiency of the phased-array beam forming IC can be improved.

In some exemplary embodiments, the system processing module or the IF and Baseband controller may be implemented as a RF beamforming IC that can control the output power of the one or more transmission elements. Such a phased-array beamforming IC can use its maximum or high output power to compensate for a scan loss when a beamforming angle becomes larger than, for example, about 50 degrees. On the other hand, if the beamforming angle is moderate or low, for example, less than about 50 degrees or at about 30 degrees, the beamforming IC may use less power than its maximum or high output power. In some exemplary embodiments, such a RF beamforming IC may provide adaptive closed loop control on the power amplifiers output power by simultaneously controlling a supply voltage and a bias current in the RF beam forming IC based on beam steering/scanning angles and based on the output power, maintaining high power efficiency. In some exemplary embodiments, such a RF beamforming IC may provide adaptive closed loop control on the power amplifiers output power by adjusting the power amplifiers' power modes (e.g. a low power mode or a high power modes) and bias current based on beam steering/scanning angles and based on the output power. As such, high power efficiency may be provided at a low power mode or at a high power mode.

In the described exemplary embodiments, by using the adaptive closed loop control and provision of sufficient/efficient output power, it is recognised that both signal-to-noise ratio (SNR) & data rates are not compromised.

The described exemplary embodiments may be used in suitable transmission applications. For example, the described exemplary embodiments may be used for SOTM (Satcom on the move) and 5G phased-array beamforming ICs and their associated applications.

The terms “coupled” or “connected” as used in this description are intended to cover both directly connected or connected through one or more intermediate means, unless otherwise stated.

The terms “configured to (perform a task/action)”, “configured for (performing a task/action)” and the like as used in this description include being programmable, programmed, connectable, wired or otherwise constructed to have the ability to perform the task/action when arranged or installed as described herein. The terms “configured to (perform a task/action)”, “configured for (performing a task/action)” and the like are intended to cover “when in use, the task/action is performed”, e.g. specifically to and/or specifically configured to and/or specifically arranged to and/or specifically adapted to do or perform a task/action.

The term “and/or”, e.g., “X and/or Y” is understood to mean either “X and Y” or “X or Y” and should be taken to provide explicit support for both meanings or for either meaning.

The terms “associated with”, “related to” and the like used herein when referring to two elements refers to a broad relationship between the two elements. The relationship includes, but is not limited to, a physical, a chemical or a biological relationship. For example, when element A is associated with element B, elements A and B may be directly or indirectly attached to each other or element A may contain element B or vice versa.

The terms “exemplary embodiment”, “example embodiment”, “exemplary implementation”, “exemplarily” and the like used herein are intended to indicate an example of matters described in the present disclosure. Such an example may relate to one or more features defined in the claims and is not necessarily intended to emphasise a best example or any essentialness of any features.

The description herein may be, in certain portions, explicitly or implicitly described as algorithms and/or functional operations that operate on data within a computer memory or an electronic circuit. These algorithmic descriptions and/or functional operations are usually used by those skilled in the information/data processing arts for efficient description. An algorithm is generally relating to a self-consistent sequence of steps leading to a desired result. The algorithmic steps can include physical manipulations of physical quantities, such as electrical, magnetic or optical signals capable of being stored, transmitted, transferred, combined, compared, and otherwise manipulated.

Further, unless specifically stated otherwise, and would ordinarily be apparent from the following, a person skilled in the art will appreciate that throughout the present specification, discussions utilizing terms such as “scanning”, “calculating”, “determining”, “replacing”, “generating”, “initializing”, “outputting”, and the like, refer to action and processes of an instructing processor/computer system, or similar electronic circuit/device/component, that manipulates/processes and transforms data represented as physical quantities within the described system into other data similarly represented as physical quantities within the system or other information storage, transmission or display devices etc.

The description also discloses relevant device/apparatus for performing the steps of the described methods. Such apparatus may be specifically constructed for the purposes of the methods, or may comprise a general purpose computer/processor or other device selectively activated or reconfigured by a computer program stored in a storage member. The algorithms and displays described herein are not inherently related to any particular computer or other apparatus. It is understood that general purpose devices/machines may be used in accordance with the teachings herein. Alternatively, the construction of a specialized device/apparatus to perform the method steps may be desired.

In addition, it is submitted that the description also implicitly covers a computer program, in that it would be clear that the steps of the methods described herein may be put into effect by computer code. It will be appreciated that a large variety of programming languages and coding can be used to implement the teachings of the description herein. Moreover, the computer program if applicable is not limited to any particular control flow and can use different control flows without departing from the scope of the invention.

Furthermore, one or more of the steps of the computer program if applicable may be performed in parallel and/or sequentially. Such a computer program if applicable may be stored on any computer readable medium. The computer readable medium may include storage devices such as magnetic or optical disks, memory chips, or other storage devices suitable for interfacing with a suitable reader/general purpose computer. In such instances, the computer readable storage medium is non-transitory. Such storage medium also covers all computer-readable media e.g. medium that stores data only for short periods of time and/or only in the presence of power, such as register memory, processor cache and Random Access Memory (RAM) and the like. The computer readable medium may even include a wired medium such as exemplified in the Internet system, or wireless medium such as exemplified in Bluetooth technology. The computer readable medium may be, for example, cloud storage in the Internet or within an intranet. The computer program when loaded and executed on a suitable reader effectively results in an apparatus that can implement the steps of the described methods, e.g. in a physical embodiment. The computer readable medium is intended to be transferable and is reproducible in that the computer program if applicable is reproducible.

The exemplary embodiments may also be implemented as hardware modules. A module is a functional hardware unit designed for use with other components or modules. For example, a module may be implemented using digital or discrete electronic components, or it can form a portion of an entire electronic circuit such as an Application Specific Integrated Circuit (ASIC). A person skilled in the art will understand that the exemplary embodiments can also be implemented as a combination of hardware and software modules.

Additionally, when describing some embodiments, the disclosure may have disclosed a method and/or process as a particular sequence of steps. However, unless otherwise required, it will be appreciated the method or process should not be limited to the particular sequence of steps disclosed. Other sequences of steps may be possible. The particular order of the steps disclosed herein should not be construed as undue limitations. Unless otherwise required, a method and/or process disclosed herein should not be limited to the steps being carried out in the order written. The sequence of steps may be varied and still remain within the scope of the disclosure.

Further, in the description herein, the word “substantially” whenever used is understood to include, but not restricted to, “entirely” or “completely” and the like. In addition, terms such as “comprising”, “comprise”, and the like whenever used, are intended to be non-restricting descriptive language in that they broadly include elements/components recited after such terms, in addition to other components not explicitly recited. For an example, when “comprising” is used, reference to a “one” feature is also intended to be a reference to “at least one” of that feature. Terms such as “consisting”, “consist”, and the like, may, in the appropriate context, be considered as a subset of terms such as “comprising”, “comprise”, and the like. Therefore, in embodiments disclosed herein using the terms such as “comprising”, “comprise”, and the like, it will be appreciated that these embodiments provide teaching for corresponding embodiments using terms such as “consisting”, “consist”, and the like. Further, terms such as “about”, “approximately” and the like whenever used, typically means a reasonable variation, for example a variation of +/−5% of the disclosed value, or a variance of 4% of the disclosed value, or a variance of 3% of the disclosed value, a variance of 2% of the disclosed value or a variance of 1% of the disclosed value.

Furthermore, in the description herein, certain values may be disclosed in a range. The values showing the end points of a range are intended to illustrate a preferred range. Whenever a range has been described, it is intended that the range covers and teaches all possible sub-ranges as well as individual numerical values within that range. That is, the end points of a range should not be interpreted as inflexible limitations. For example, a description of a range of 1% to 5% is intended to have specifically disclosed sub-ranges 1% to 2%, 1% to 3%, 1% to 4%, 2% to 3% etc., as well as individually, values within that range such as 1%, 2%, 3%, 4% and 5%. It is to be appreciated that the individual numerical values within the range also include integers, fractions and decimals. Furthermore, whenever a range has been described, it is also intended that the range covers and teaches values of up to 2 additional decimal places or significant figures (where appropriate) from the shown numerical end points. For example, a description of a range of 1% to 5% is intended to have specifically disclosed the ranges 1.00% to 5.00% and also 1.0% to 5.0% and all their intermediate values (such as 1.01%, 1.02% . . . 4.98%, 4.99%, 5.00% and 1.1%, 1.2% . . . 4.8%, 4.9%, 5.0% etc.,) spanning the ranges. The intention of the above specific disclosure is applicable to any depth/breadth of a range.

The described exemplary embodiments are described as having one or more transmission elements. It will be appreciated that such transmission elements may be an array or a phased-array of transmission elements. Such transmission elements may be one or more beamforming arrays and/or one or more transmitter chains. In addition, the one or more transmission elements of the described exemplary embodiments may be a subset or be nestled within a larger system of transmission elements. In such circumstances, the desired beam scanning angle of the one or more transmission elements, can be a combination with the larger system of transmission elements.

In the described exemplary embodiments, the desired beam scanning angle and the output power are understood to be associated with the desired beam scanning angle and the output power of the beamforming transmission system, i.e. as a combination of the one or more transmission elements.

In some described exemplary embodiments, some components have not been described or shown for simplicity. It will be appreciated that components from other exemplary embodiments may also be present in such exemplary embodiments. For example, components such as power combiners and/or power dividers etc. may be included in the exemplary embodiments described with reference to, for example, FIG. 2, FIG. 3 and FIG. 8.

In the described exemplary embodiments, the coupling or connections between components may be wired connections, wireless connections or a combination of both wired and wireless connections.

In the described exemplary embodiments, references to a beam scanning angle also apply to a beam steering angle.

In the described exemplary embodiments, a beam scanning angle of about 50 degrees may have been described as when scanning loss occurs. One reason the beam steering angle of 50 degrees is used for illustration herein is because for conventional systems, at beam steering angles from 50 degrees and above, the scan loss becomes significant. For such systems, the scan loss at 30 degrees, for example, is less than 0.8 dB. It will be appreciated that such angles are illustrative and provided as examples only. That is, scanning loss may occur at different angles in different applications. For example, significant scanning loss may occur at 45 degrees in some applications, or 60 degrees in other applications. Further, the angles described herein are with respect to a predetermined axis of transmission that is in turn with respect to one or more antennas of a transmission system. It will be appreciated that such an axis and angles are illustrative and provided as examples only. That is, scanning loss may occur with different orientations in different applications.

In the described exemplary embodiments, a low power mode and a high power mode have been described. It will be appreciated that a low power mode or low output power is for a scenario or situation whereby it is determined that the scan loss for the beam scanning angle is low, i.e. no need for a high output power or a maximum output power of the beamforming transmission system. An example for a low output power may be about 8 dBm (compare FIG. 4, FIGS. 6A and 6B). It will be appreciated that such a value may change depending on the application. Next, it will be appreciated that a high power mode or high output power is for a scenario or situation whereby it is determined that the scan loss for the beam scanning angle is significant or high e.g. about 5 db loss or more, i.e. a need for a high output power of the beamforming transmission system. An example for a high output power may be about 10 dBm (compare FIG. 4). It will be appreciated that such a value may change depending on the application. It will also be appreciated that a high power mode or high output power is not necessarily the maximum output power of the beamforming transmission system.

It will be appreciated by a person skilled in the art that other variations and/or modifications may be made to the specific embodiments without departing from the scope of the claimed invention as broadly described. For example, in the description herein, features of different exemplary embodiments may be mixed, combined, interchanged, incorporated, adopted, modified, included etc. or the like across different exemplary embodiments. For example, exemplary embodiments are not necessarily mutually exclusive as some may be combined with one or more embodiments to form new exemplary embodiments. Furthermore, it will be appreciated that while the present disclosure provides embodiments having one or more of the features/characteristics discussed herein, one or more of these features/characteristics may also be disclaimed in other alternative embodiments and the present disclosure provides support for such disclaimers and these associated alternative embodiments. The present embodiments are, therefore, to be considered in all respects to be illustrative and not restrictive.

1. A beamforming transmission system, the system comprising,
one or more transmission elements, the one or more transmission elements each comprising
a power amplifier;
an antenna coupled to the power amplifier; and
a power detector coupled to the antenna;
a power controller coupled to the power amplifier;
a system processing module coupled to the one or more transmission elements, the system processing module further coupled to the power controller, the system processing module being arranged to instruct the power controller to control an output power of the power amplifier;
wherein the system processing module is arranged to determine a desired beam scanning angle of the one or more transmission elements and to obtain a present output power of the power amplifier from the power detector; and
further wherein the system processing module is arranged to instruct the power controller to control the output power of the power amplifier based on both the desired beam scanning angle and the present output power of the power amplifier.

2. The beamforming transmission system as claimed in claim 1, further comprising the system processing module being arranged to instruct the power controller to control the output power of the power amplifier based on one of at least a first operating point of the power amplifier and a second operating point of the power amplifier.

3. The beamforming transmission system as claimed in claim 2, further comprising the system processing module being arranged to instruct the power controller to control the output power of the power amplifier using the first operating point of the power amplifier at a first power mode and using the second operating point of the power amplifier at a second power mode, the first power mode and the second power mode being based on both the desired beam scanning angle and the present output power of the power amplifier.

4. The beamforming transmission system as claimed in claim 2, wherein the first operating point comprises a first predetermined set of values of a supply voltage and a supply current to the power amplifier and the second operating point comprises a second predetermined set of values of the supply voltage and the supply current to the power amplifier.

5. The beamforming transmission system as claimed in claim 4, wherein the power controller comprises a supply voltage generator coupled to the power amplifier and a separate bias current generator coupled to the power amplifier, both the supply voltage generator and the bias current generator being coupled to the system processing module; and
wherein the system processing module is arranged to simultaneously adjust the supply voltage generator and the separate bias current generator based on the one of at least a first operating point of the power amplifier and a second operating point of the power amplifier to provide the respective supply voltage and the supply current to the power amplifier.

6. The beamforming transmission system as claimed in claim 5, wherein the respective supply voltage and the supply current to the power amplifier are adjustable independently of each other.

7. The beamforming transmission system as claimed in claim 3, wherein the power controller comprises a power mode controller coupled to the power amplifier and a bias current generator coupled to the power amplifier, both the power mode controller and the bias current generator being coupled to the system processing module; and
wherein the system processing module is arranged to switch on or off the power amplifier, the switch on or off being independent of at least one other power amplifier of the one or more transmission elements.

8. The beamforming transmission system as claimed in claim 7, wherein the system processing module is arranged to switch on or off the power amplifier based on the one of at least a first operating point of the power amplifier and a second operating point of the power amplifier.

9. The beamforming transmission system as claimed in claim 1, further comprising a memory component to store one or more settings for the system processing module to instruct the power controller to control the output power of the power amplifier based on both the desired beam scanning angle and the present output power of the power amplifier.

10. A method of controlling an output power of a beamforming transmission system that comprises one or more transmission elements, the one or more transmission elements each comprising a power amplifier; an antenna coupled to the power amplifier; and a power detector coupled to the antenna, the method comprising,
determining a desired beam scanning angle of the one or more transmission elements;
obtaining a present output power of the power amplifier from the power detector;
controlling, using a power controller of the beamforming transmission system, the output power of the power amplifier based on both the desired beam scanning angle and the present output power of the power amplifier.

11. The method as claimed in claim 10, further comprising controlling the output power of the power amplifier based on one of at least a first operating point of the power amplifier and a second operating point of the power amplifier.

12. The method as claimed in claim 11, further comprising controlling the output power of the power amplifier using the first operating point of the power amplifier at a first power mode and using the second operating point of the power amplifier at a second power mode, the first power mode and the second power mode being based on both the desired beam scanning angle and the present output power of the power amplifier.

13. The method as claimed in claim 11, wherein the first operating point comprises a first predetermined set of values of a supply voltage and a supply current to the power amplifier and the second operating point comprises a second predetermined set of values of the supply voltage and the supply current to the power amplifier.

14. The method as claimed in claim 13, further comprising providing a supply voltage generator coupled to the power amplifier and a separate bias current generator coupled to the power amplifier; and
simultaneously adjusting the supply voltage generator and the separate bias current generator based on the one of at least a first operating point of the power amplifier and a second operating point of the power amplifier to provide the respective supply voltage and the supply current to the power amplifier.

15. The method as claimed in claim 14, further comprising adjusting the respective supply voltage and the supply current to the power amplifier independently of each other.

16. The method as claimed in claim 12, further comprising providing a power mode controller coupled to the power amplifier and a bias current generator coupled to the power amplifier; and
switching on or off the power amplifier, the switching on or off being independent of at least one other power amplifier of the one or more transmission elements.

17. The method as claimed in claim 16, further comprising switching on or off the power amplifier based on the one of at least a first operating point of the power amplifier and a second operating point of the power amplifier.

18. The method as claimed in claim 10, further comprising storing one or more settings in a memory component of the beamforming transmission system, the one or more settings for instructing the power controller to control the output power of the power amplifier based on both the desired beam scanning angle and the present output power of the power amplifier.

19. A computer readable storage medium having stored thereon software instructions that, when executed by a system processing module of a beamforming transmission system, cause the system processing module to perform a method of claim 10.
